(19) United States
(12) Patent Application Publication
(10) Pub. No.: US 2004/0171180 A1
(43) Pub. Date: Sep. 2, 2004

(54) Monitoring of VCSEL output power with photodiodes

(76) Inventor: Anthony L. Moretti, St. Charles, IL (US)

Correspondence Address: MOLEX INCORPORATED, 2222 WELLINGTON COURT, LISLE, IL, 60532, US

(21) Appl. No.: 10/376,202

(22) Filed: Feb. 27, 2003

(51) Int. Cl. H01L 21/00

(52) U.S. Cl. 438/22

(57) ABSTRACT

Improved power output sensing of radiation from a plurality of transmitting vertical cavity surface emitting lasers (VCSELs) arranged in a array and attached to a submount. At least one, and preferably two power monitoring VCSELs are also formed on the submount at a location where indirect radiation is not detected from the transmitting VCSELs in the array. Power monitoring VCSELs are formed on flip-chips, preferably on the same wafer as the VCSEL array to provide similar electrical characteristics. The flip-chip VCSELs are mounted to the submount such that the power monitoring VCSELs are generally in alignment with the photodiodes. The photodiodes then produce electrical signals due to radiation emitted by the power monitoring VCSELs, which in turn emulates the amount of radiation emitted by the transmitting VCSELs in the array. Related methods of forming a VCSEL array attached to a submount, with power monitoring of flip-chip VCSELs by photodiodes formed in the submount, is also disclosed.

### FIELD OF THE INVENTION

The present invention relates generally to the field of optical transmitters, and more particularly to monitoring the power output of vertical cavity surface emitting laser (VCSEL) arrays.

### BACKGROUND OF THE INVENTION

Multiple channel optical transmitting modules are frequently utilized to transmit data over multiple channels in an optical communication system. VCSEL arrays that are known to the art typically consist of multiple VCSELs that are usually disposed in a row. For example, a typical VCSEL structure may include 12 VCSELs aligned in a row. The power emitted by the VCSELs may vary due to a number of circumstances, such as changes in temperature and due to aging. It is therefore desirable to monitor the intensity or the power of the laser radiation, such as for purposes of maintaining the transmitted power within a safe range. It is normally desirable to keep the VCSEL power levels below a level that could be potentially damaging to an individual's eyes or within levels specified in eye safety standards or regulations.

One way of sensing the optical power transmitted by a VCSEL array is disclosed in International Patent Application WO 99/29000, published on Jun. 10, 1999. The structure disclosed in this application includes a linear array of 12 VCSELs and two additional VCSELs. The two additional VCSELs are disposed at each end of the linear array and are used for power monitoring purposes. The VCSEL array is attached to a silicon submount, which serves as a carrier for mechanical, thermal, and electrical management. Spacers are also attached to the submount, with one spacer adjacent to each of the two power-monitoring VCSELs. A photodiode on a chip is then flipped and attached to the spacer and is disposed over the respective power-monitoring VCSEL in a cantilevered style such that the light emitted from the power-monitoring VCSEL strikes the active region of the photodiode.

This power-sensing configuration works well, but it has some disadvantages. Among the disadvantages are the extra manufacturing costs associated with the cantilevered power sensing arrangement, including the difficulties encountered in accurately mounting and aligning the photodiodes over the respective VCSELs, and the extra costs associated with making a custom 14 VCSEL array as compared to the more conventional 12 VCSEL array.

There is therefore a need for a less expensive structure for monitoring the power transmitted by a VCSEL array. There is also a need for a VCSEL array that is simpler and more efficient to manufacture.

Accordingly, it is a general object of the present invention to provide a new and improved VCSEL array with monitoring of the laser radiation power levels.

Another object of the present invention is to provide power monitoring of a VCSEL array that is attached to a submount, with one or more photodiodes formed in the submount with the VCSEL array and one or more power monitoring VCSELs formed on flip-chips that are disposed over the photodiodes to sense VCSEL power levels.

Yet another object of the present invention is to provide VCSELs formed on flip-chips that are processed together with the VCSEL arrays on the same semiconductor wafer such that the VCSELs in the array and the VCSELs on the flip-chips have similar and predictable electrical characteristics.

### SUMMARY OF THE INVENTION

The present invention is directed to a VCSEL array, such as for use in an optical communication system, with improved sensing of power output levels of the VCSEL array.

The present invention has particular applicability to VCSEL arrays having a plurality of transmitting VCSELs arranged in a row, in multiple rows or a single VCSEL. The VCSEL array is attached to a submount and at least one photodiode is also formed on the submount. A monitoring VCSEL is formed on a flip-chip with the flip-chip preferably processed from the same semiconductor wafer as the VCSEL array such that the monitoring VCSEL on the flip-chip has similar electrical characteristics to the transmitting VCSELs in the array. The monitoring VCSEL on the flip-chip is disposed over the photodiode on the submount during the manufacturing process such that the photodiode measures the power output of the flip-chip VCSEL as an accurate predictor of the power output of similar transmitting VCSELs in the array.

The present invention also relates to methods of forming the flip-chip VCSELs on the same semiconductor wafer as for the VCSEL arrays to provide similar electrical characteristics for the flip-chip VCSELs compared with the VCSELs in the array. One or more photodiodes are formed on the submount to which the array of VCSELs is attached, but distanced therefrom such that the photodiodes do not indirectly sense radiation from the VCSELs in the array. After the VCSEL arrays and flip-chip VCSELs are separated from the wafer, the flip-chip VCSELs are mounted onto the submount such that the flip-chip VCSELs are generally in alignment with respective photodiodes in the submount. Each photodiode then provides an electrical signal that is representative of the power emitted by the flip-chip VCSELs. The flip-chip VCSELs, in turn, emulate the power emitted by the transmitting VCSELs in the array.

### BRIEF DESCRIPTION OF THE DRAWINGS

The invention, together with the further objects and advantages thereof, may best be understood by reference to the following description taken in conjunction with the accompanying drawings, in the figures in which like reference numerals identify like elements, and in which:

FIG. 1 is a top plan view of a prior art VCSEL array that is attached to a submount with two additional VCSELs that are monitored for power by means of cantilevered photodiodes overlying the two additional VCSELs;

FIG. 2 is a side elevational view of the prior art VCSEL array shown in FIG. 1;

FIG. 3 is a top plan view of a VCSEL array attached to a submount in accordance with the present invention, with power monitoring of flip-chip VCSELs by means of one or more photodiodes formed in the submount; and with the flip-chip VCSELs disposed over the photodiodes;

FIG. 4 is a side elevational view of the VCSEL array and submount shown in FIG. 3;

FIG. 5 is a top plan view of a semiconductor wafer with VCSEL arrays and flip-chip VCSELs formed on the same semiconductor wafer in accordance with the present invention; and

FIG. 6 is a top plan view of a VCSEL formed on a flip-chip.

### DESCRIPTION OF THE PREFERRED EMBODIMENTS

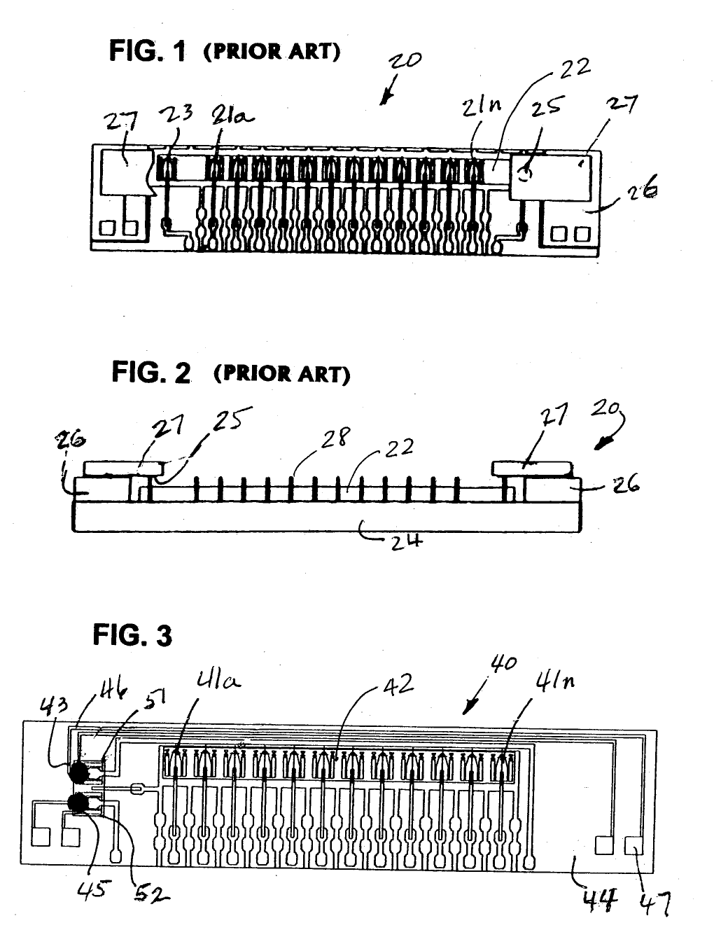

Shown in FIGS. 1 and 2 is a prior art multi-channel optical transmitting device, generally designated 20, which may be used to transmit data over multiple channels such as through multiple optical waveguides, including multimode or single mode optical fibers. Multiple individual lasers of the vertical cavity surface emitting laser (VCSEL) type, such as VCSELs 21a through 21n (collectively referred to as VCSELs 21), may be fabricated in an array 22 in the side-by-side relationship depicted in FIG. 1. In the example of FIG. 1, twelve VCSELs 21 are arranged in a row. VCSELs 21 typically emit laser radiation in a direction perpendicular to the top surface of the array 22 shown in FIG. 1.

The VCSEL array 22 is attached to a submount 24. A plurality of wirebonds 28 provides electrical connection between the VCSEL array 22 and the submount 24.

Such multi-channel optical transmitting devices 20 include a control system to monitor and adjust the intensity or optical power of the VCSELs 21, typically to achieve a constant power output that is within acceptable limits, or to limit the peak power output. To this end, an additional monitoring VCSEL 23 is disposed on either side of the transmitting VCSELs 21 to monitor the power of the transmitting VCSELs 21. The monitoring VCSELs 23 are intended to emulate the effective radiation output of the transmitting VCSELs 21, but are dedicated to the power monitoring portion of device 20.

In the prior art embodiment shown in FIGS. 1 and 2, a power sensor 25, such as a photodiode, is disposed directly above each power monitoring VCSEL 23, opposite to the optically active zone of the monitoring VCSEL 23 to monitor the optical power emitted by the monitoring VCSELs. As best seen in FIG. 2, a spacer 26 is mounted to the submount 24 by a bonding agent, such as an adhesive, such that a spacer 26 is adjacent to each power monitoring VCSEL 23. A chip 27 with the photodiode power sensor 25 is then mounted to the top surface of spacer 26 such that a portion of chip 27, including power sensor 25, extends beyond spacer 26 in a cantilevered fashion. Power sensor 25 is then disposed above monitoring VCSEL 27. It will be appreciated that a portion of chip 27 on the left side of FIG. 1 is broken away so that the monitoring VCSEL 23 may be seen. The power sensors 25 thus project over and above the monitoring VCSELs 23 at an elevated level as seen in FIG. 2. This cantilevered arrangement is also sometimes referred to as a “diving board” arrangement. Since the sensors 25 are at an elevated position relative to the VCSEL array 22, sensors 25 may be susceptible to stray radiation from the nearest transmitting VCSELs 21. This could, of course, have the undesirable effect of interfering with the accuracy of measuring the radiation emitted by the monitoring VCSELs 23.

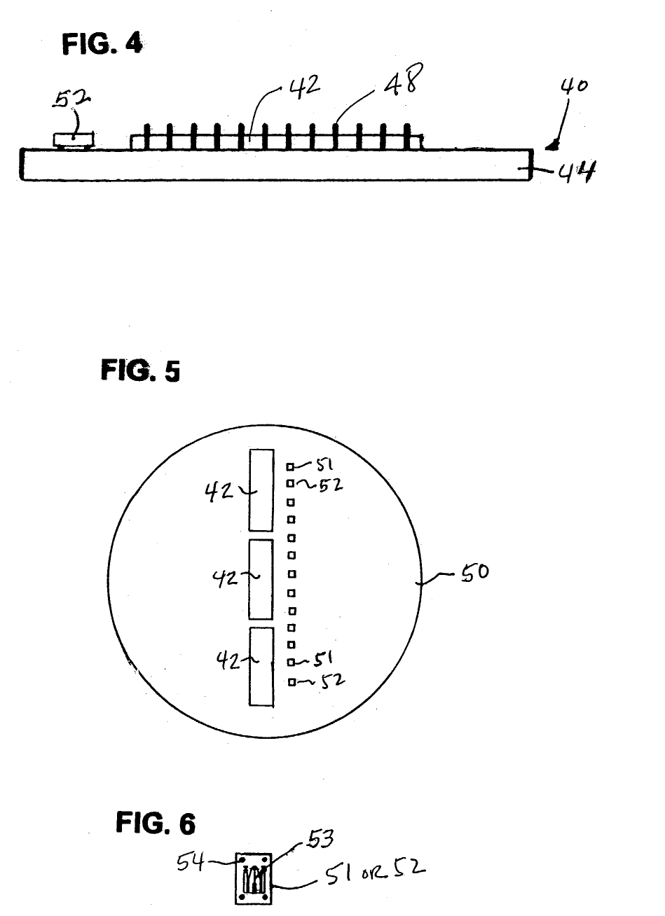

With reference to FIGS. 3 and 4, a multi-channel optical transmitting device, generally designated 40, is constructed in accordance with the present invention. A VCSEL array 42 consists of a plurality of individual VCSELs, such as VCSEL 41a through 41n (collectively referred to as VCSELs 41). VCSELs 41 are preferably formed in a row in the side-by-side relationship shown in FIG. 3. In the example of FIG. 3, twelve VCSELs 41 are arranged in a row as a VCSEL array 42. However, the VCSEL array 42 could consist of multiple rows of VCSELs, or even an individual VCSEL. As with the prior art example in FIGS. 1 and 2, transmitting VCSELs 41 emit optical radiation in a direction perpendicular to the top surface of the VCSEL array 42 shown in FIG. 3.

The multi-channel optical transmitting device 40 has an improved and cost effective optical power sensing arrangement. In accordance with one aspect of the present invention, device 40 of FIGS. 3 and 4 eliminates the need for the dual diving board assemblies used in the prior art device 20 as shown in FIGS. 1 and 2, including the spacers 26 and the cantilevered photodiode sensors 27. Thus, in the embodiment shown in FIGS. 3 and 4, array 42 has 12 VCSELs, rather than the 14 VCSELs of array 22.

VCSEL array 42 is preferably formed from an epitaxial growth on a wafer of gallium-arsenide (GaAs) material and is attached to a submount 44. Submount 44 is preferably made from float zone silicon so as to have a low level of conductivity. A plurality of wirebonds 48 provides electrical interconnection between the VCSEL array 42 and the submount 44. However, other means of electrical interconnection may also be provided.

Device 40 preferably has two power sensors, such as two photodiodes 43 and 45 that are formed in submount 44. For example, photodiodes 43 and 45 may be metal-semiconductor-metal (MSM) photodiodes that can be formed from semiconductor manufacturing processes that are compatible with the processes used to fabricate many semiconductor devices, including CMOS processes. As shown in FIG. 3, it may be desirable to fabricate the photodiodes on the same end of submount 44. Alternatively, the photodiodes may be fabricated with one photodiode at each end of submount 44. In any event, photodiodes 43 and 45 are preferably disposed away from the VCSEL array 42 to avoid indirectly sensing signals from VCSELs 41. Alternatively, PIN photodiodes could be fabricated on the submount 44 in place of the MSM photodiodes. However, the manufacturing processes for fabricating PIN photodiodes on the silicon submount are generally more complex than for MSM photodiodes.

Separate flip-chip VCSELs 53 are preferably fabricated as separate flip-chips 51 and 52 along with the VCSEL arrays 42 on the same GaAs wafer 50, as seen in FIG. 5. A flip-chip VCSEL 51 or 52 is also illustrated in FIG. 6. It will be appreciated that, for purposes of illustration, VCSEL arrays 42 and flip-chips 51 and 52 are not drawn to scale in FIG. 5. Of course, two or more VCSELs 53 for power monitoring could also be fabricated on a single flip-chip, if desired. The power monitoring VCSELs 53 on flip-chips 51 and 52 will then have virtually the same electrical characteristics as the transmitting VCSELs 41 in the VCSEL arrays 42. The flip-chip power monitoring VCSELs 53 can thus be expected to operate similarly to transmitting VCSELs 41, and to accurately track or emulate the operating power of the transmitting VCSELs 41. After the VCSEL arrays 42 and flip-chips 51 and 52 are fabricated, flip-chips 51 and 52 may have solder balls 54 added to provide suitable electrical contacts between the flip-chips and the submount 44, as well as to affix the flip-chip to the submount.

The two flip-chips 51 and 52 are then flip-chip mounted to submount 44 such that each of the power monitoring VCSELs 53 is disposed over or above respective photodiodes 43 and 45, with the emission apertures of these VCSELs generally aligned with the photodiodes. When the VCSELs are powered up, including the flip-chip VCSELS 53, photodiodes 43 and 45 are illuminated by the laser radiation from flip-chip VCSELs 53. Photodiodes 43 and 45 then generate photocurrent that can be used for monitoring the power of the similar transmitting VCSELs 41. The amount of photocurrent generated by photodiodes 43 and 45 is related to the intensity of the laser radiation generated by the power monitoring flip-chip VCSELs 53.

In a manner known to the art, a plurality of metal lines, such as line 46, is brought out to a plurality of bonding pads, such as to pad 47, to provide electrical connections to the VCSELs 53 and to the photodiodes 43 and 45.

While particular embodiments of the invention have been shown and described, it will be apparent to those skilled in the art that changes and modifications may be made thereto without departing from the invention in its broader aspects.

1. Apparatus for monitoring the power radiated by a plurality of VCSELs in an array, said apparatus comprising:
a submount;
a plurality of VCSELs formed in an array, the plurality of VCSELs formed in the array attached to the submount;
a photodiode formed on the submount; and
a VCSEL formed on a flip-chip, said VCSEL formed on
the flip-chip having electrical characteristics similar to the plurality of VCSELs formed in the array,
said flip-chip mounted to said submount such that the
VCSEL formed on the flip-chip is generally in alignment with said photodiode whereby said photodiode receives illumination from said VCSEL on the flip-chip and provides an electrical signal representative of the optical power emitted by the VCSELs formed in the array.

2. The apparatus as claimed in claim 1 further comprising:
a second photodiode formed on the submount;
a second flip-chip; and
a second VCSEL formed on a second flip-chip, said second VCSEL formed on the second flip-chip having electrical characteristics similar to the plurality of VCSELs formed in the array;
said second flip-chip mounted to said submount such that the second VCSEL formed on the second flip-chip is generally in alignment with said second photodiode whereby said second photodiode receives illumination from said second VCSEL on the second flip-chip and provides a second electrical signal representative of the optical power emitted by the VCSELs formed in the array.

3. The apparatus as claimed in claim 1 wherein said VCSEL array and said VCSEL formed on the flip-chip are formed on the same wafer.

4. The apparatus as claimed in claim 3, wherein said wafer is of gallium arsenide (Ga As) material.

5. The apparatus as claimed in claim 1 wherein said photodiode is spaced away from the VCSELs in the array to avoid sensing any radiation from any of the VCSELs in the array.

6. The apparatus as claimed in claim 2 wherein said photodiode and said second photodiode are both disposed adjacent to one another at one end of the submount.

7. The apparatus as claimed in claim 2 wherein said photodiode and said second photodiode are both of the metal-semiconductor-metal type.

8. The apparatus of claim 1, wherein said submount is of a photoconductive material.

9. A method of fabricating apparatus for monitoring the power radiated by a plurality of VCSELs in an array, said method comprising the steps of:
forming a submount from a photoconductive material;
forming at least one photodiode in the submount;
forming a plurality of VCSELs in an array on a wafer;
forming at least one power monitoring VCSEL on a flip-chip on the same wafer;
separating the VCSEL array and the power monitoring VCSEL flip-chip as separate components from said wafer;
attaching the plurality of VCSELs formed in the array to the submount;
mounting said at least one power monitoring VCSEL flip-chip onto the submount such that the power monitoring VCSEL on said at least one flip-chip is generally in alignment with said at least one photodiode to receive illumination from the power monitoring VCSEL on said at least one flip-chip; and
providing at least one electrical signal from the power monitoring VCSEL on said at least on flip-chip that is representative of the optical power emitted by the plurality of VCSELs formed in the array.

10. The method as claimed in claim 9 wherein the steps of forming said at least one photodiode in the submount include forming at least one photodiode of the metal-semiconductor-metal type.

11. The method as claimed in claim 9, wherein the steps of forming said plurality of VCSELS in an array on a wafer include forming said VCSEL array from an epitaxial growth on a wafer of gallium arsenide (Ga As) material.

12. The method as claimed in claim 9, wherein the steps of forming a submount include forming said submount from a silicon material.

13. A method of fabricating apparatus for monitoring the power radiated by a plurality of VCSELs in an array, said method comprising the steps of:
forming a submount from a photo conductive material;
forming at least one photodiode in the submount;
forming a plurality of VCSELs in an array on a wafer;
forming at least one power monitoring VCSEL on a flip-chip;
attaching the plurality of VCSELs formed in the array to the submount;
mounting said at least one power monitoring VCSEL flip-chip onto the submount such that the power monitoring VCSEL on said at least one flip-chip is generally in alignment with said at least one photodiode to receive illumination from the power monitoring VCSEL on said at least one flip-chip; and
providing at least one electrical signal from the power monitoring VCSEL on said at least on flip-chip that is representative of the optical power emitted by the plurality of VCSELs formed in the array.
